(19) United States
(12) Patent Application Publication
(10) Pub. No.: US 2025/0379557 A1
(43) Pub. Date: Dec. 11, 2025

(54) ACOUSTIC FILTER DEVICE INCLUDING AN ACOUSTIC FILTER AND ONE OR MORE INTEGRATED PASSIVE DEVICES

(71) Applicant: QUALCOMM Incorporated, San Diego, CA (US)

(72) Inventors: Changhan Hobie YUN, San Diego, CA (US); Sebastian BRUNNER, Graz (AT); Christian HOFFMANN, Bad Feilnbach (DE); Manfred STADLER, Seiersberg (AT); Edgar Konrad SCHMIDHAMMER, Stein an der Traun (DE); Horst DROESCHER, Frauental an der Laßnitz (AT); Manuel HOFER, Graz (AT); Stefan Leopold HATZL, Kloech (AT); Rodrigo PACHER FERNANDES, Deutschlandsberg (AT); Juergen PORTMANN, München (DE); Florian FEIL, Gauting (DE); Doosoub SHIN, Incheon (KR)

(21) Appl. No.: 18/734,829

(22) Filed: Jun. 5, 2024

(51) Int. Cl. H03H 9/56; H01Q 1/22; H03H 3/02; H03H 9/17

(52) U.S. Cl. CPC H03H 9/56; H01Q 1/22; H03H 3/02; H03H 9/17

(57) ABSTRACT

An acoustic filter device includes an acoustic filter. The acoustic filter device also includes one or more structural layers forming one or more curved domes that define one or more cavities of the acoustic filter. The acoustic filter device further includes one or more integrated passive device (IPD) layers on the one or more structural layers.

### FIELD

Various features relate to acoustic filter integrated circuit devices.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Acoustic filters are used for filtering acoustic signals and may be used in wireless communication devices, such as for implementing radio frequency (RF) filters. As the number of frequency bands used in wireless communication increases and as the frequency band used widens, the performance of acoustic filters increases in importance to reduce losses and increase overall performance of electronic devices. A smaller acoustic filter device that includes an acoustic filter and integrated passive devices can be used in electronic devices having size constraints.

### SUMMARY

Various features relate to integrated circuit devices.

One example provides an acoustic filter device that includes an acoustic filter. The acoustic filter device also includes one or more structural layers forming one or more curved domes that define one or more cavities of the acoustic filter. The acoustic filter device further includes one or more integrated passive device (IPD) layers on the one or more structural layers.

Another example provides a method of fabricating an acoustic filter device. The method includes forming one or more structural layers on an acoustic filter substrate of an acoustic filter. The method also includes forming one or more curved domes in at least one of the one or more structural layers. The one or more curved domes define one or more cavities of the acoustic filter. The method further includes forming one or more integrated passive device (IPD) layers on the one or more structural layers.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a cross-sectional profile view of an exemplary acoustic filter device.

FIG. 1B illustrates a cross-sectional profile view of an exemplary acoustic filter device.

FIG. 2A illustrates a cross-sectional profile view of an exemplary acoustic filter device.

FIG. 2B illustrates a cross-sectional profile view of an exemplary acoustic filter device.

FIG. 3 illustrates a cross-sectional profile view of an exemplary acoustic filter device.

FIG. 4A illustrates a cross-sectional profile view of an exemplary acoustic filter device.

FIG. 4B illustrates a cross-sectional profile view of an exemplary acoustic filter device.

FIG. 4C illustrates a cross-sectional profile view of an exemplary acoustic filter device.

FIG. 5 illustrates a cross-sectional profile view of an exemplary acoustic filter device.

FIG. 6 illustrates a cross-sectional profile view of an exemplary acoustic filter device.

FIG. 7 illustrates a cross-sectional profile view of an exemplary acoustic filter device.

FIG. 8 illustrates a cross-sectional profile view of an exemplary acoustic filter device.

FIG. 9 illustrates a cross-sectional profile view of an exemplary acoustic filter device.

FIG. 10 illustrates a cross-sectional profile view of an exemplary acoustic filter device.

FIG. 11 illustrates a cross-sectional profile view of an exemplary acoustic filter device.

FIG. 12 illustrates a cross-sectional profile view of an exemplary acoustic filter device.

FIG. 13 illustrates a cross-sectional profile view of an exemplary acoustic filter device.

FIG. 14 illustrates a cross-sectional profile view of an exemplary acoustic filter device.

FIG. 15A illustrates a first part of exemplary sequences for fabricating acoustic filter devices.

FIG. 15B illustrates a second part of exemplary sequences for fabricating acoustic filter devices.

FIG. 16 illustrates a third part of an exemplary sequence for fabricating the exemplary acoustic filter device of FIG. 1A.

FIG. 17 illustrates a third part of an exemplary sequence for fabricating the exemplary acoustic filter device of FIG. 1B.

FIG. 18 illustrates an exemplary flow diagram of a method of semiconductor fabrication for an acoustic filter device.

FIG. 19 illustrates various electronic devices that may integrate an exemplary acoustic filter device described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. For example, acoustic filters are used for filtering acoustic signals and may be used for implementing RF filters in wireless communication devices. As the number of frequency bands used in wireless communication increases and as the frequency band widens, the performance of acoustic filters increases in importance to reduce losses and increase overall performance of electronic devices.

Various aspects of the present disclosure provide an acoustic filter device that includes an acoustic filter and one or more IPD layers. The acoustic filter has one or more cavities defined by one or more curved domes. In an example, a cavity of the acoustic filter corresponds to a protective chamber defined by a curved dome. In some aspects, the acoustic filter device can include one or more antenna layers. The acoustic filter device including the acoustic filter and the IPD layer(s), and optionally the antenna layer(s), can achieve higher performance and compact footprint. In an example, when the protective chamber has a curved dome, the protective chamber provides improved mechanical stability, e.g., as compared to a flat protective chamber. In another example, when the antenna layer(s) are contoured to correspond to a shape of the curved dome of the protective chamber, the antenna layer(s) have enhanced directivity and higher reflectance, e.g., as compared to flat antenna layer(s).

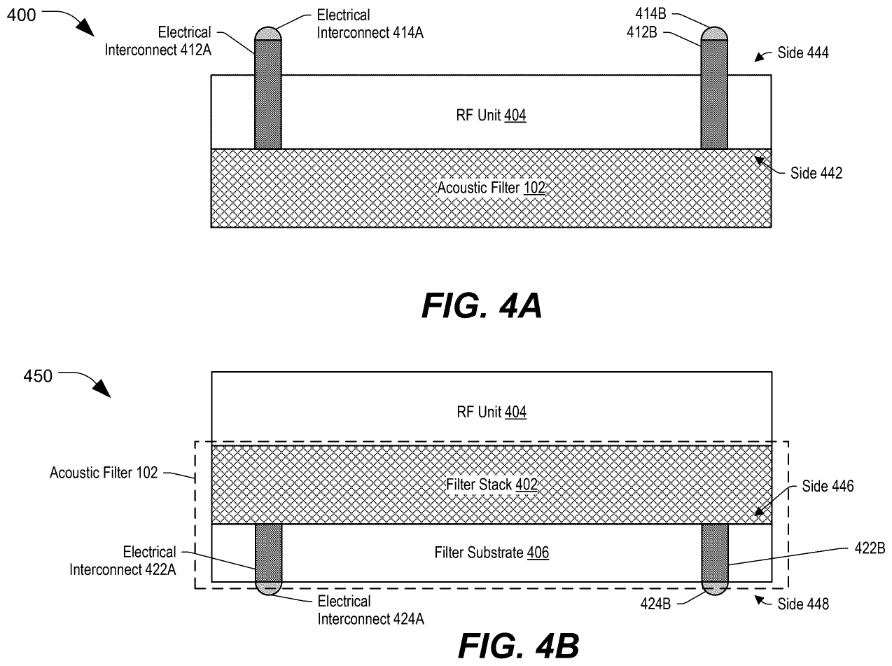

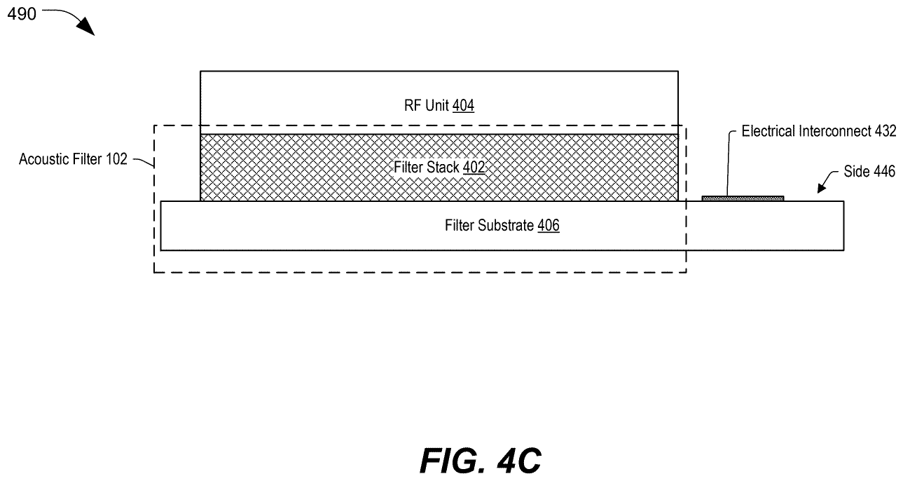

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 4A, multiple electrical interconnects are illustrated and associated with reference numbers 412A and 412B. When referring to a particular one of these electrical interconnects, such as an electrical interconnect 412A, the distinguishing letter “A” is used. However, when referring to any arbitrary one of these electrical interconnects or to these electrical interconnects as a group, the reference number 412 is used without a distinguishing letter.

### Exemplary Implementations of an Acoustic Filter Device

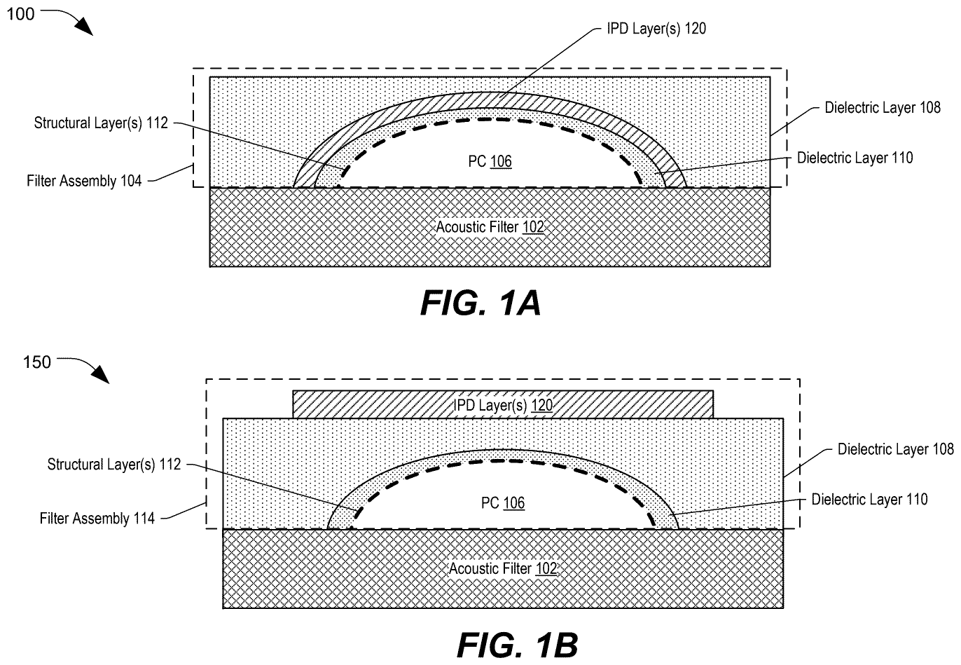

FIG. 1A illustrates a cross-sectional profile view of an exemplary device 100 (e.g., an acoustic filter device) that includes an acoustic filter and one or more integrated passive devices. In the implementation shown in FIG. 1A, the device 100 includes an acoustic filter 102 and a filter assembly 104. In some aspects, the acoustic filter 102 includes a filter substrate, piezoelectric materials, conductors, dielectrics, or a combination thereof. In some implementations, the acoustic filter 102 includes a surface acoustic wave (SAW) filter or a bulk acoustic wave (BAW) filter.

The filter assembly 104 includes a protective chamber (PC) 106 of the acoustic filter 102. The protective chamber 106 is defined by one or more structural layers 112 and the acoustic filter 102. For example, the structural layer(s) 112 form a curved dome that defines the protective chamber 106 on a portion of the acoustic filter 102. In an example, one or more of the structural layer(s) 112 form one or more curved domes that define one or more cavities of the acoustic filter 102. To illustrate, a cavity of the acoustic filter 102 corresponds to the protective chamber 106. The protective chamber 106 is configured (e.g., designed) to protect a surface of the acoustic filter 102, e.g., from contaminants. For example, the acoustic filter 102 includes a resonating structure and the protective chamber 106 provides a protective space to prevent any material from contaminating a surface above the resonating structure. In a particular aspect, the protective chamber 106 corresponds to an air or vacuum cavity. In some aspects, the structural layer(s) 112 include metal, oxide, nitride, or a combination thereof. The acoustic filter 102 having a single cavity that corresponds to the protective chamber 106 is provided as an illustrative example, in other examples the acoustic filter 102 can have multiple cavities that can correspond to multiple protective chambers.

The filter assembly 104 also includes one or more integrated passive device (IPD) layers 120 on the structural layer(s) 112. For example, the filter assembly 104 includes the IPD layer(s) 120 formed on a dielectric layer 110 that is formed on the structural layer(s) 112. The dielectric layer 110 is contoured on the structural layer(s) 112 to correspond to a shape of the one or more curved domes of the one or more cavities of the acoustic filter 102. For example, the dielectric layer 110 is contoured on the structural layer(s) 112 to correspond to a shape of the curved dome of the protective chamber 106. The IPD layer(s) 120 are contoured on the dielectric layer 110 to correspond to the shape of the one or more curved domes of the one or more cavities of the acoustic filter 102. For example, the IPD layer(s) 120 are contoured on the dielectric layer 110 to correspond to the shape of the curved dome of the protective chamber 106. The IPD layer(s) 120 include at least one metal layer, at least one dielectric layer, or a combination thereof. The at least one metal layer, the at least one dielectric layer, or a combination thereof, are included in a functioning filter, a matching network, a transmission line, an antenna feed, or a combination thereof. The IPD layer(s) 120 correspond to one or more passive devices, such as a capacitor, a resistors, an inductor, an impedance matching network, a balun, a coupler, a divider, a diplexer, another type of passive device, or a combination thereof. In some aspects a device region (e.g., corresponding to one or more passive devices) can extend beyond a region corresponding to the one or more cavities. For example, the IPD layer(s) 120, the dielectric layer 110, or both, can extend on either side of the PC 106 on a surface (e.g., a flat region) of the acoustic filter 102.

In some aspects, the filter assembly 104 includes a dielectric layer 108 on the IPD layer(s) 120. The dielectric layer 110 is formed of a first dielectric material and the dielectric layer 108 is formed of a second dielectric material. In some implementations, the first dielectric material (e.g., silicon dioxide) is the same as the second dielectric material. In other implementations, the first dielectric material (e.g., silicon dioxide) is distinct from the second dielectric material (e.g., silicon nitride).

It should be understood that the device 100 may include additional components, other components, fewer components, or a combination thereof, to support the functionality described herein. As non-limiting examples, the device 100 may include additional integrated circuit (IC) devices, additional layers, additional dies, additional packages, additional interconnects, additional structures, other components, different components, or a combination thereof, to support the functionality and technical advantages disclosed herein.

The device 100 including the acoustic filter 102 and the IPD layer(s) 120 can achieve higher performance and compact footprint. A technical advantage of the curved dome of a cavity (e.g., the protective chamber 106) of the acoustic filter 102 is improved mechanical stability as compared to a flat protective chamber.

In a particular implementation, the device 100 includes an acoustic filter (e.g., the acoustic filter 102). The device 100 also includes one or more structural layers (e.g., the structural layer(s) 112) forming one or more curved domes that define one or more cavities (e.g., the PC 106) of the acoustic filter. The device 100 further includes one or more IPD layers (e.g., the IPD layer(s) 120) on the one or more structural layers. The one or more IPD layers are contoured to correspond to a shape of the one or more curved domes.

FIG. 1B illustrates a cross-sectional profile view of an exemplary device 150 that includes an acoustic filter and one or more integrated passive devices. In the implementation shown in FIG. 1B, the device 150 includes the acoustic filter 102 and a filter assembly 114.

The filter assembly 114 includes the IPD layer(s) 120 formed on the dielectric layer 108. As an example, the filter assembly 114 includes one or more cavities (e.g., including the PC 106) of the acoustic filter 102. As an example, the structural layer(s) 112 form one or more curved domes that define the one or more cavities (e.g., at least the PC 106) on a portion of the acoustic filter 102.

The filter assembly 104 also includes the IPD layer(s) 120 on the structural layer(s) 112. For example, the filter assembly 104 includes the dielectric layer 110 formed on the structural layer(s) 112. The dielectric layer 110 is contoured on the structural layer(s) 112 to correspond to a shape of the one or more curved domes of the one or more cavities of the acoustic filter 102. For example, the dielectric layer 110 is contoured on the structural layer(s) 112 to correspond to a shape of the curved dome of the PC 106. The filter assembly 104 also includes a dielectric layer 108 formed on the dielectric layer 110.

The dielectric layer 110 is formed of a first dielectric material and the dielectric layer 108 is formed of a second dielectric material. In some implementations, the first dielectric material (e.g., silicon dioxide) is the same as the second dielectric material. In other implementations, the first dielectric material (e.g., silicon dioxide) is distinct from the second dielectric material (e.g., silicon nitride). The IPD layer(s) 120 are formed on a surface of the dielectric layer 108. In the implementation illustrated in FIG. 1B, the IPD layer(s) 120 are relatively flat and are not contoured to correspond to the shape of the one or more curved domes of the one or more cavities (e.g., the PC 106).

It should be understood that the device 150 may include additional components, other components, fewer components, or a combination thereof, to support the functionality described herein. As non-limiting examples, the device 150 may include additional integrated circuit (IC) devices, additional layers, additional dies, additional packages, additional interconnects, additional structures, other components, different components, or a combination thereof, to support the functionality and technical advantages disclosed herein.

The device 150 including the acoustic filter 102 and the IPD layer(s) 120 can achieve higher performance and compact footprint. A technical advantage of the curved dome of the protective chamber 106 is improved mechanical stability as compared to a flat protective chamber.

In a particular implementation, the device 150 includes an acoustic filter (e.g., the acoustic filter 102). The device 150 also includes one or more structural layers (e.g., the structural layer(s) 112) forming one or more curved domes that define one or more cavities (e.g., the PC 106) of the acoustic filter. The device 150 further includes one or more IPD layers (e.g., the IPD layer(s) 120) on the one or more structural layers.

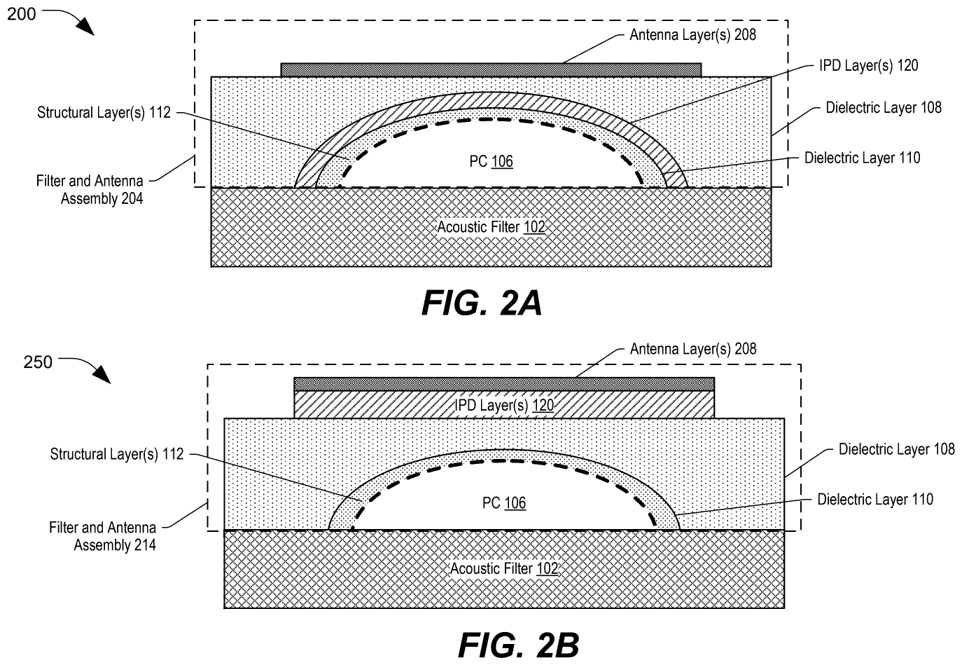

FIG. 2A illustrates a cross-sectional profile view of an exemplary device 200 (e.g., an acoustic filter device). In the implementation shown in FIG. 2A, the device 200 includes the acoustic filter 102 and a filter and antenna assembly 204.

The filter and antenna assembly 204 corresponds to one or more antenna layers 208 formed on the filter assembly 104 of FIG. 1A. For example, the antenna layer(s) 208 are formed on a surface of the dielectric layer 108. The antenna layer(s) 208 include metal, such as aluminum, copper, gold, silver, tungsten, or a combination thereof. In some implementations, the antenna layer(s) 208 can include traces, pads, patches, loops, or other geometries based on target operating frequencies and performance characteristics.

FIG. 2B illustrates a cross-sectional profile view of an exemplary device 250 (e.g., an acoustic filter device). In the implementation shown in FIG. 2B, the device 250 includes the acoustic filter 102 and a filter and antenna assembly 214.

The filter and antenna assembly 214 corresponds to one or more antenna layers 208 formed on the filter assembly 114 of FIG. 1B. For example, the antenna layer(s) 208 are formed on a surface of the IPD layer(s) 120. In the implementations illustrated in FIGS. 2A-2B, the antenna layer(s) 208 are relatively flat and are not contoured to correspond to the shape of one or more curved domes (e.g., the curved dome) of one or more cavities (e.g., the PC 106) of the acoustic filter 102.

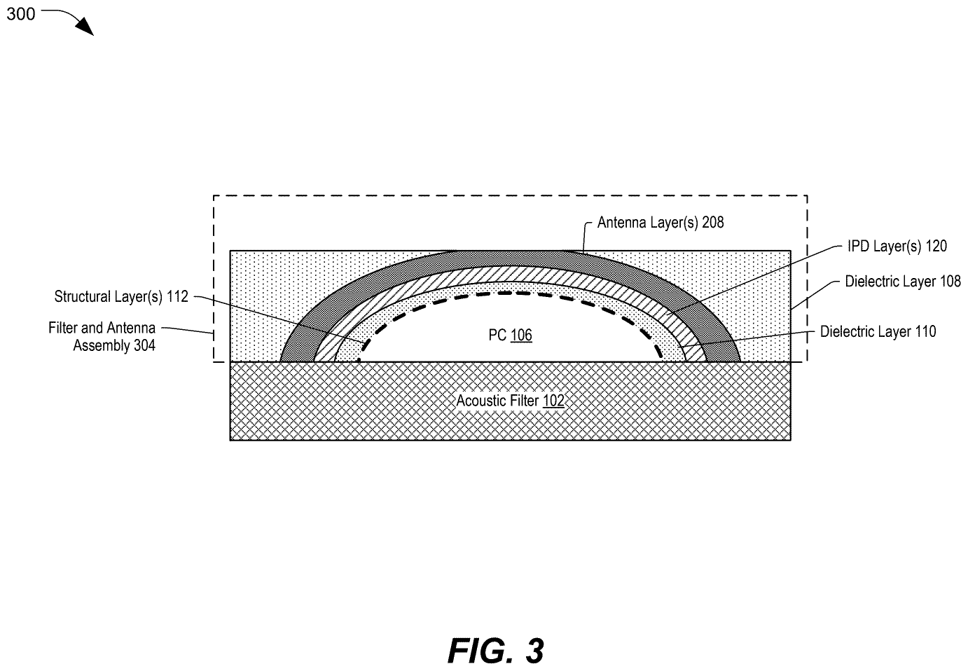

FIG. 3 illustrates a cross-sectional profile view of an exemplary device 300 (e.g., an acoustic filter device). In the implementation shown in FIG. 3, the device 300 includes the acoustic filter 102 and a filter and antenna assembly 304.

The filter and antenna assembly 304 corresponds to one or more antenna layers 208 formed between the IPD layer(s) 120 and the dielectric layer 108 of the filter assembly 104 of FIG. 1A. For example, the antenna layer(s) 208 are formed on a surface of the dielectric layer 110 and the dielectric layer 108 is formed on the antenna layer(s) 208. The antenna layer(s) 208 are contoured on the dielectric layer 110 to correspond to the shape of the curved dome of the PC 106. A technical advantage of the antenna layer(s) 208 being contoured to correspond to the shape of the curved dome of the PC 106 includes the antenna layer(s) 208 having enhanced directivity and higher reflectance, e.g., as compared to flat antenna layer(s).

FIG. 4A illustrates a cross-sectional profile view of an exemplary device 400 (e.g., an acoustic filter device). In the implementation shown in FIG. 4A, the device 400 includes the acoustic filter 102, a radio frequency (RF) unit 404, and one or more electrical interconnect(s) 412 that extend through the RF unit 404.

In a particular aspect, the RF unit 404 corresponds to the filter assembly 104 of FIG. 1A, the filter assembly 114 of FIG. 1B, the filter and antenna assembly 204 of FIG. 2A, the filter and antenna assembly 214 of FIG. 2B, or the filter and antenna assembly 304 of FIG. 3.

The electrical interconnect(s) 412 extend from a side 442 of the RF unit 404 to a side 444 of the RF unit 404 to electrically connect the acoustic filter 102 on the side 442 to corresponding electrical interconnects 414 on the side 444. For example, the device 400 includes an electrical interconnect 412A that extends through the RF unit 404 to electrically connect the acoustic filter 102 on the side 442 to an electrical interconnect 414A on the side 444. As another example, the device 400 includes an electrical interconnect 412B that extends through the RF unit 404 to electrically connect the acoustic filter 102 on the side 442 to an electrical interconnect 414B on the side 444. Although the device 400 is described as including two electrical interconnects 412 extending through the RF unit 404, in other examples the device 400 can include fewer than two or more than two electrical interconnects 412 extending through the RF unit 404.

In some implementations, the electrical interconnect(s) 412 correspond to conductive pillars or vias. In some implementations, the electrical interconnect(s) 414 correspond to conductive bumps or pads. In some aspects the electrical interconnect(s) 412 include a first conductive material (e.g., a metal or metal alloy), and the electrical interconnects 414 include a second conductive material (e.g., a metal or metal alloy). In some implementations, the first conductive material is the same as the second conductive material. In other implementations, the first conductive material (e.g., copper) is distinct from the second conductive material (e.g., solder).

The electrical interconnect(s) 414 can be used to electrically connect the acoustic filter 102 to one or more other components (e.g., integrated circuitry of a die) of the device 400, one or more off-device components, or a combination thereof. For example, the electrical interconnect(s) 412, 414 can be used to receive a data signal that is processed using the acoustic filter 102 and the IPD layer(s) 120 of the RF unit 404 to generate a processed data signal that is transmitted by the antenna layer(s) 208 of the RF unit 404. As another example, a data signal is received using the antenna layer(s) 208 of the RF unit 404 and processed using the IPD layer(s) 120 of the RF unit 404 and the acoustic filter 102 to generate a processed data signal that is output via the electrical interconnect(s) 412, 414.

FIG. 4B illustrates a cross-sectional profile view of an exemplary device 450 (e.g., an acoustic filter device). In the implementation shown in FIG. 4B, the device 450 includes the acoustic filter 102, the RF unit 404, and one or more electrical interconnects 422 that extend through a filter substrate 406 of the acoustic filter 102.

The acoustic filter 102 includes a filter stack 402 formed on the filter substrate 406. For example, the filter stack 402 includes one or more of piezoelectric layers, metal layers, dielectric layers, capping layers, bonding layers, or a combination thereof. In a particular aspect, the filter stack 402 is configured (e.g., designed) to attenuate or block unwanted frequencies. The filter substrate 406 includes substrate material, such as quartz, fused silica, silicon dioxide (SiO₂), lithium tantalate, lithium niobate, aluminum nitride, langasite, langatate, glass, ceramic, aluminum oxide (Al₂O₃), alumina, sapphire, silicon, gallium arsenide, or a combination thereof.

The electrical interconnect(s) 422 extend from a side 446 of the filter substrate 406 to a side 448 of the filter substrate 406 of the acoustic filter 102 to electrically connect the filter stack 402 of the acoustic filter 102 on the side 446 to corresponding electrical interconnects 424 on the side 448. For example, the device 450 includes an electrical interconnect 422A that extends through the filter substrate 406 to electrically connect the filter stack 402 on the side 446 to an electrical interconnect 424A on the side 448. As another example, the device 450 includes an electrical interconnect 422B that extends through the filter stack 402 to electrically connect the filter stack 402 on the side 446 to an electrical interconnect 424B on the side 448. Although the device 450 is described as including two electrical interconnects 422 extending through the filter substrate 406, in other examples the device 450 can include fewer than two or more than two electrical interconnects 422 extending through the filter substrate 406.

In some implementations, the electrical interconnect(s) 422 correspond to conductive pillars or vias. In some implementations, the electrical interconnect(s) 424 correspond to conductive bumps or pads. In some aspects the electrical interconnect(s) 422 include a first conductive material (e.g., a metal or metal alloy), and the electrical interconnects 424 include a second conductive material (e.g., a metal or metal alloy). In some implementations, the first conductive material is the same as the second conductive material. In other implementations, the first conductive material (e.g., copper) is distinct from the second conductive material (e.g., solder).

The electrical interconnect(s) 424 can be used to electrically connect the acoustic filter 102 (e.g., the filter stack 402) to one or more other components (e.g., integrated circuitry of a die) of the device 450, one or more off-device components, or a combination thereof. For example, the electrical interconnect(s) 422, 424 can be used to receive a data signal that is processed by the acoustic filter 102 (e.g., the filter stack 402) and the IPD layer(s) 120 of the RF unit 404 to generate a processed data signal that is transmitted by the antenna layer(s) 208 of the RF unit 404. As another example, a data signal is received by the antenna layer(s) 208 of the RF unit 404 and processed by the IPD layer(s) 120 of the RF unit 404 and the acoustic filter 102 (e.g., the filter stack 402) to generate a processed data signal that is output via the electrical interconnect(s) 412, 414.

FIG. 4C illustrates a cross-sectional profile view of an exemplary device 490 (e.g., an acoustic filter device). In the implementation shown in FIG. 4C, the device 490 includes the acoustic filter 102, the RF unit 404, and an electrical interconnect 432 that is formed on the side 446 of the filter substrate 406. For example, the electrical interconnect 432 is formed on the same side (e.g., the side 446) of the filter substrate 406 that has the filter stack 402 and the RF unit 404. The filter stack 402 is electrically connected via (e.g., conductive paths on or through) the filter substrate 406 to the electrical interconnect 432.

In some implementations, the electrical interconnect 432 corresponds to a conductive pillar, bump, or pad. In some aspects the electrical interconnect 432 includes a conductive material (e.g., a metal or metal alloy). The electrical interconnect 432 can be used to electrically connect the acoustic filter 102 (e.g., the filter stack 402) to one or more other components (e.g., integrated circuitry of a die) of the device 490, one or more off-device components, or a combination thereof. For example, the electrical interconnect 432 can be used to receive a data signal that is processed using the acoustic filter 102 (e.g., the filter stack 402) and the IPD layer(s) 120 of the RF unit 404 to generate a processed data signal that is transmitted by the antenna layer(s) 208 of the RF unit 404. As another example, a data signal is received by the antenna layer(s) 208 of the RF unit 404 and processed by the IPD layer(s) 120 of the RF unit 404 and the acoustic filter 102 (e.g., the filter stack 402) to generate a processed data signal that is output via the electrical interconnect 432.

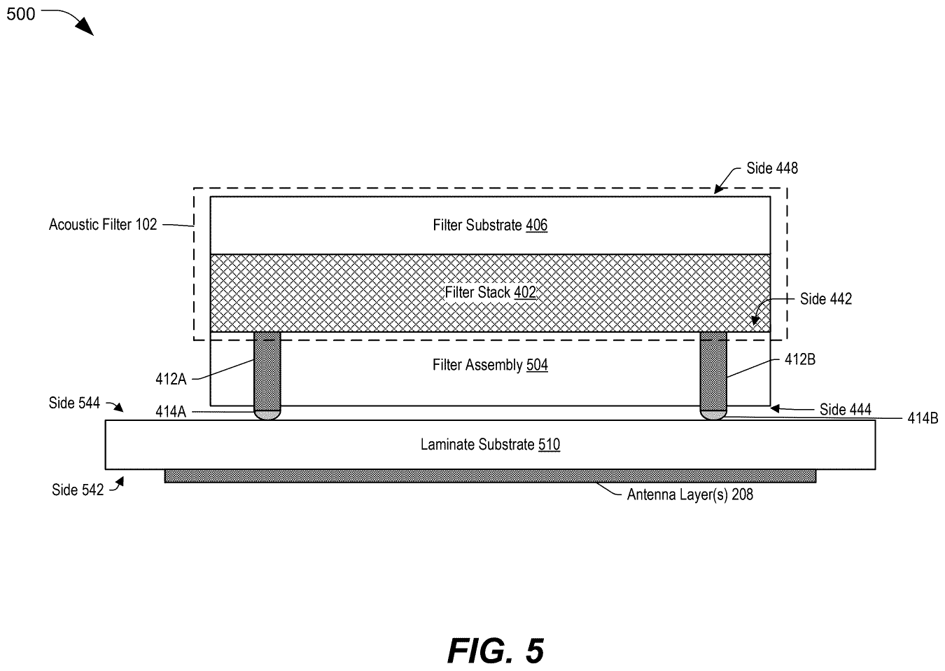

FIG. 5 illustrates a cross-sectional profile view of an exemplary device 500 (e.g., an acoustic filter device). In the implementation shown in FIG. 5, the device 500 includes the acoustic filter 102, a filter assembly 504, the antenna layer(s) 208, and a laminate substrate 510. The laminate substrate 510 is between the acoustic filter 102 and the one or more antenna layers 208.

In an example, the antenna layer(s) 208 are formed on a side 542 of the laminate substrate 510, and the acoustic filter 102 is electrically connected via the electrical interconnects 412, 414 to a side 544 of the laminate substrate 510. In a particular aspect, the laminate substrate 510 includes a laminate substrate material, such as a polymer (e.g., prepreg, polymide, epoxy, acrylic), a dielectric, a ceramic, alumina, aluminum nitride, or a combination thereof. In a particular aspect, the laminate substrate 510 includes one or more conductive layers (e.g., metal layers) to electrically connect the electrical interconnects 414 to the one or more antenna layers 208. For example, the acoustic filter 102, the filter assembly 504, or both, can be electrically connected via the laminate substrate 510 to the antenna layer(s) 208.

In a particular aspect, the device 500 includes a filter assembly 504 between the acoustic filter 102 and the laminate substrate 510. In an example, the filter assembly 504 corresponds to an implementation of the RF unit 404 of FIG. 4A that includes the filter assembly 104 of FIG. 1A or the filter assembly 114 of FIG. 1B. In a particular aspect, the laminate substrate 510 is between the filter assembly 504 (e.g., including the IPD layer(s) 120 and the PC 106) and the antenna layer(s) 208.

The electrical interconnect(s) 412 extend through the filter assembly 504 (e.g., the RF unit 404) from the side 442 to the side 444 to electrically connect the acoustic filter 102 (e.g., the filter stack 402) on the side 442 to the electrical interconnect(s) 414 on the side 444, as described with reference to FIG. 4A. The electrical interconnect(s) 414 are electrically connected to a side 544 of the laminate substrate 510 and the antenna layer(s) 208 are formed on the side 542 of the laminate substrate 510. The antenna layer(s) 208 are relatively flat and are not contoured to correspond to a shape of one or more curved domes of one or more cavities (e.g., a PC 106) of the filter assembly 504.

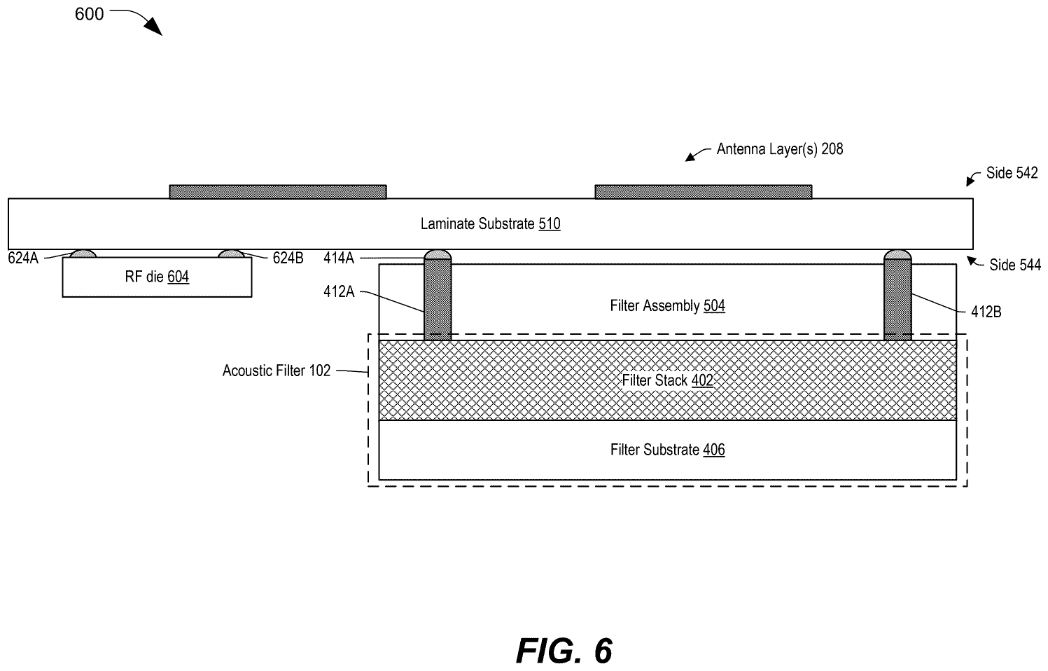

FIG. 6 illustrates a cross-sectional profile view of an exemplary device 600 (e.g., an acoustic filter device). In the implementation shown in FIG. 6, the device 600 includes the acoustic filter 102, the antenna layer(s) 208, the filter assembly 504, the laminate substrate 510, and an RF die 604. The RF die 604 is coupled to the side 544 of the laminate substrate 510.

In an example, the RF die 604 is on the same side (e.g., the side 544) of the laminate substrate 510 as the filter assembly 504 (e.g., the IPD layer(s) 120, the PC 106, or both) and the acoustic filter 102 (e.g., the filter substrate 406, the filter stack 402, or both). The laminate substrate 510 is between the antenna layer(s) 208 and the RF die 604. For example, the antenna layer(s) 208 are on the side 542 of the laminate substrate 510.

The RF die 604 is electrically connected via one or more electrical interconnects 624 to the side 544 of the laminate substrate 510. For example, the RF die 604 is electrically connected via an electrical interconnect 624A and an electrical interconnect 624B to the laminate substrate 510.

In a particular aspect, the RF die 604 is electrically connected via (e.g., metal layers of) the laminate substrate 510 to the antenna layer(s) 208, the filter assembly 504, the acoustic filter 102, or a combination thereof. For example, the RF die 604 can provide a data signal to the filter assembly 504 and the acoustic filter 102 to generate a processed data signal that is transmitted using the antenna layer(s) 208. In another example, the antenna layer(s) 208 can receive a data signal that is provided to the filter assembly 504 and the acoustic filter 102 to generate a processed data signal that is provided to the RF die 604.

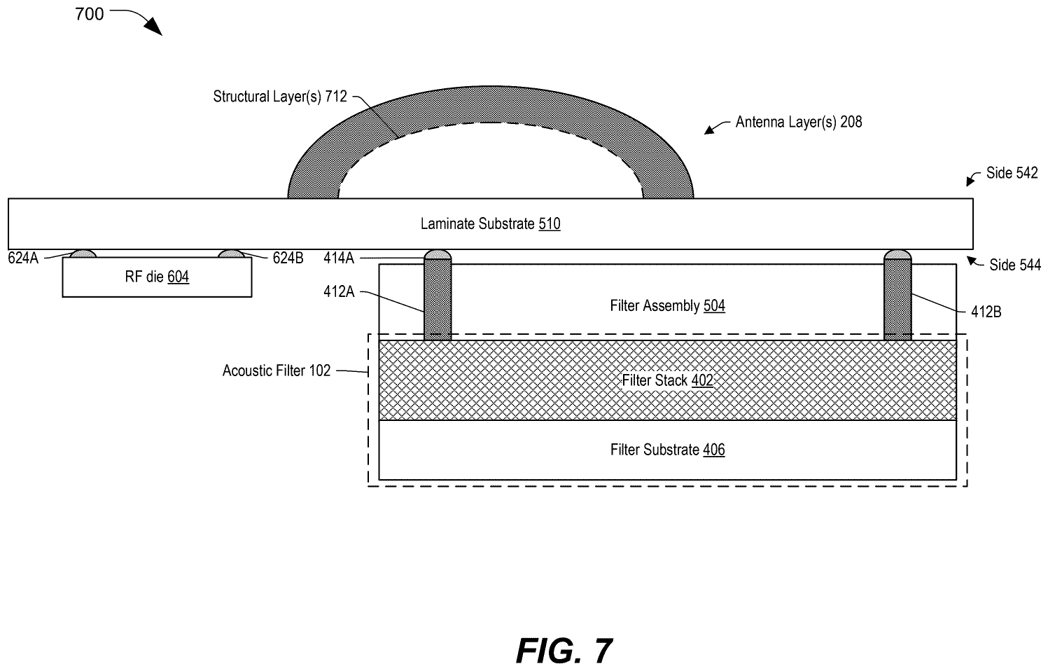

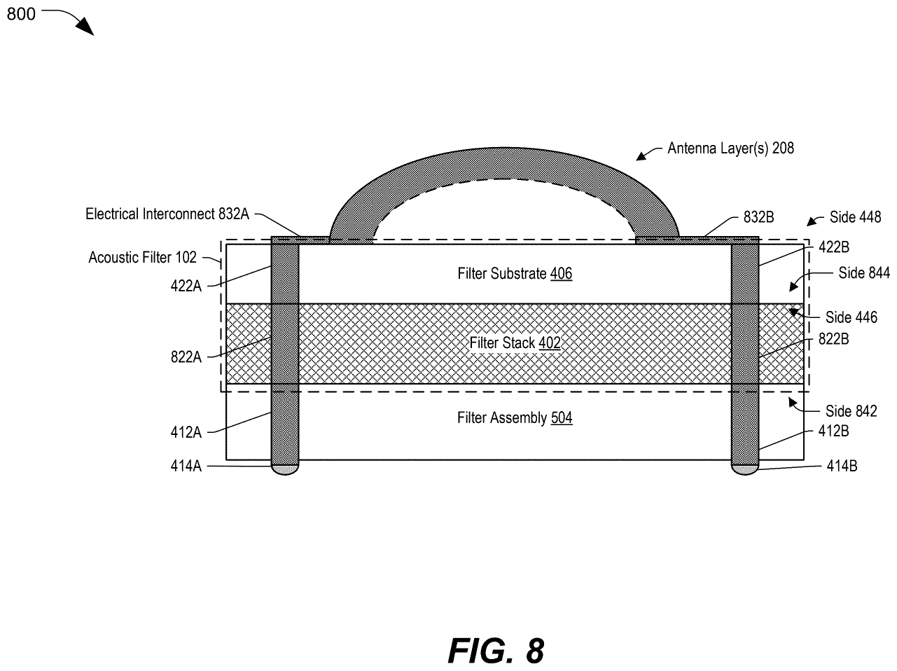

FIG. 7 illustrates a cross-sectional profile view of an exemplary device 700 (e.g., an acoustic filter device). In the implementation shown in FIG. 7, the device 700 includes the acoustic filter 102, the antenna layer(s) 208, the filter assembly 504, the laminate substrate 510, and the RF die 604. The antenna layer(s) 208 are contoured to have a curved shape.

In an example, the antenna layer(s) 208 are formed on one or more structural layers 712 that are contoured to have a curved shape. A technical advantage of the antenna layer(s) 208 contoured to correspond to a curved shape includes the antenna layer(s) 208 having enhanced directivity and higher reflectance, e.g., as compared to flat antenna layer(s).

FIG. 8 illustrates a cross-sectional profile view of an exemplary device 800 (e.g., an acoustic filter device). In the implementation shown in FIG. 8, the device 800 includes the acoustic filter 102, the antenna layer(s) 208, and the filter assembly 504. The device 800 includes one or more electrical interconnects 822 that extend from a side 842 of the filter stack 402 to a side 844 of the filter stack 402.

In an example, the acoustic filter 102 is between the antenna layer(s) 208 and the filter assembly 504. To illustrate, the antenna layer(s) 208 are formed on the side 448 of the filter substrate 406. The filter stack 402 is formed on the filter substrate 406. For example, the side 446 of the filter substrate 406 is adjacent to the side 844 of the filter stack 402. The filter assembly 504 is formed on the side 842 of the filter stack 402.

The electrical interconnect(s) 822 are connected to the electrical interconnect(s) 412 that extend through the filter assembly 504 and to the electrical interconnect(s) 422 that extend through the filter substrate 406. For example, an electrical interconnect 822A and an electrical interconnect 822B extend from the side 842 to the side 844 of the filter stack 402. The electrical interconnect 822A is connected to the electrical interconnect 412A and to the electrical interconnect 422A. The electrical interconnect 822B is connected to the electrical interconnect 412B and to the electrical interconnect 422B.

The device 800 includes one or more electrical interconnects 832 on the side 448 of the filter substrate 406 connecting the antenna layer(s) 208 to the electrical interconnect(s) 422. For example, an electrical interconnect 832A connects the antenna layer(s) 208 to the electrical interconnect 422A, and an electrical interconnect 832B connects the antenna layer(s) 208 to the electrical interconnect 422B. In some implementations, the antenna layer(s) 208 are contoured to have a curved shape. In other implementations, the antenna layer(s) 208 are relatively flat.

The electrical interconnects 414, 412, 822, 422, and 832 can be used to exchange data signals with the antenna layer(s) 208. For example, the electrical interconnects 414A, 412A can be used to receive a data signal that is processed by the filter assembly 504 and the filter stack 402 to generate a processed data signal that is provided through the electrical interconnects 412A, 822A, 422A, 832A to the antenna layer(s) 208 for transmission. As another example, a data signal is received using the antenna layer(s) 208 and provided via the electrical interconnects 832B, 422B, 822B, and 412B to the filter stack 402 and the filter assembly 504 to generate a processed data signal that is output via the electrical interconnects 412B, 414B.

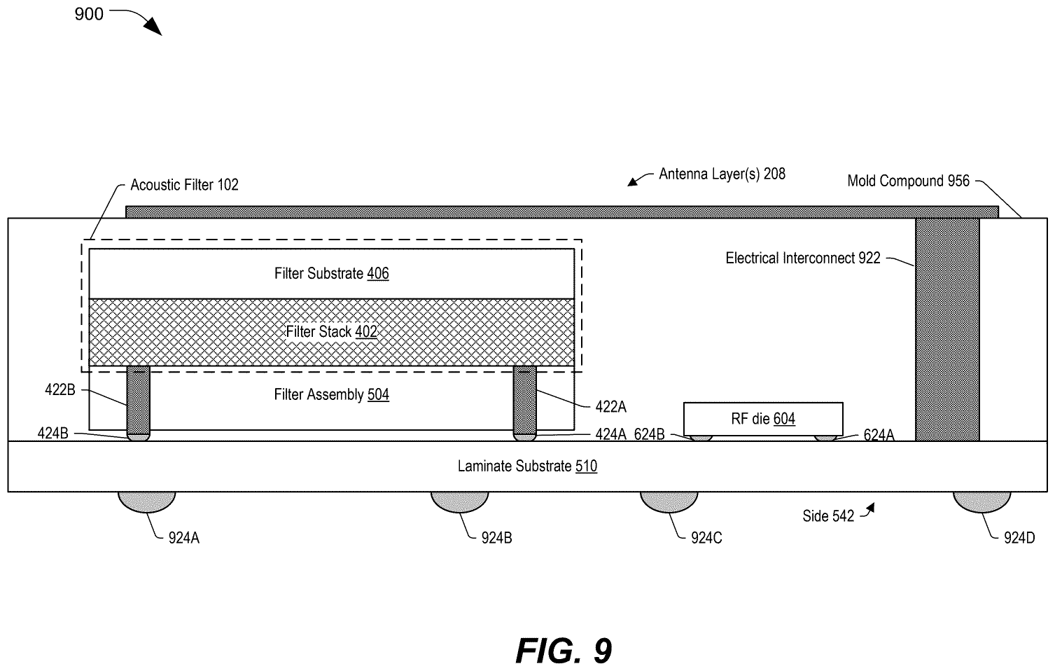

FIG. 9 illustrates a cross-sectional profile view of an exemplary device 900 (e.g., an acoustic filter device). In the implementation shown in FIG. 9, the device 900 includes the acoustic filter 102, the filter assembly 504 and the RF die 604 on the laminate substrate 510. The acoustic filter 102, the filter assembly 504, and the RF die 604 are at least partially encapsulated in a mold compound 956.

The antenna layer(s) 208 are formed on a surface of the mold compound 956. In some implementations, the antenna layer(s) 208 are relatively flat. In other implementations, the antenna layer(s) 208 are contoured to have a curved shape.

The antenna layer(s) 208 are connected via an electrical interconnect 922 to the laminate substrate 510. For example, the electrical interconnect 922 is connected via (e.g., conductive layers of) the laminate substrate 510 to the electrical interconnect(s) 624 of the RF die 604, the electrical interconnect(s) 424 of the filter assembly 504, or both.

In some implementations, the device 900 includes one or more electrical interconnects 924, such as electrical interconnects 924A, 924B, 924C, 924D, on the side 542 of the laminate substrate 510. In an example, the electrical interconnect(s) 924 connect (e.g., the conductive layers of) the laminate substrate 510 to other components of the device 900, one or more off-device components, or a combination thereof.

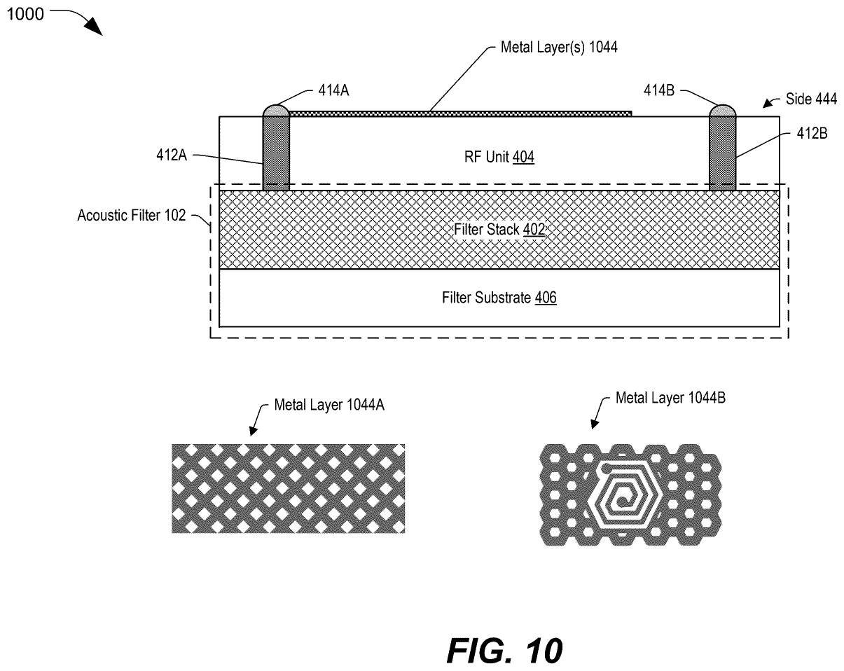

FIG. 10 illustrates a cross-sectional profile view of an exemplary device 1000 (e.g., an acoustic filter device). In the implementation shown in FIG. 10, the device 1000 includes the acoustic filter 102, the RF unit 404, and one or more metal layers 1044 that are formed on the RF unit 404. FIG. 10 illustrates a top view of an exemplary metal layer 1044A and a top view of an exemplary metal layer 1044B. Other designs of metal layers 1044 are possible.

In some implementations, the metal layer(s) 1044 include a metal or metal alloy. In some aspects, the metal layer(s) 1044 include at least one of a reinforcement layer, an electromagnetic interference (EMI) shielding layer, a heat spreader, an inductor-resistor-capacitor (LRC) layer, a functional layer, an antenna feed, a matching network, a micro strip line, a transmission line, an antenna, or a routing layer.

In the implementation illustrated in FIG. 10, the metal layer(s) 1044 are formed on the side 444 of the RF unit 404 and are connected to the electrical interconnect(s) 414. For example, the metal layer(s) 1044 are connected to the electrical interconnect 414A, 414B, or both. In some aspects, the metal layer(s) 1044 can be formed at various surfaces of the devices 100, 150, 200, 250, 300, 400, 450, 490, 500, 600, 700, 800, 900, 1000, or a combination thereof. For example, the metal layer(s) 1004 can be formed on (e.g., under or above) the acoustic filter 102, one or more curved domes of one or more cavities of the acoustic filter 102, the curved dome of the PC 106, the structural layer(s) 112, the dielectric layer 110, the dielectric layer 108, the IPD layer(s) 120, the antenna layer(s) 208, the RF unit 404, the filter stack 402, the filter substrate 406, the filter assembly 504, the laminate substrate 510, the RF die 604, the structural layers 712, the mold compound 956, or a combination thereof.

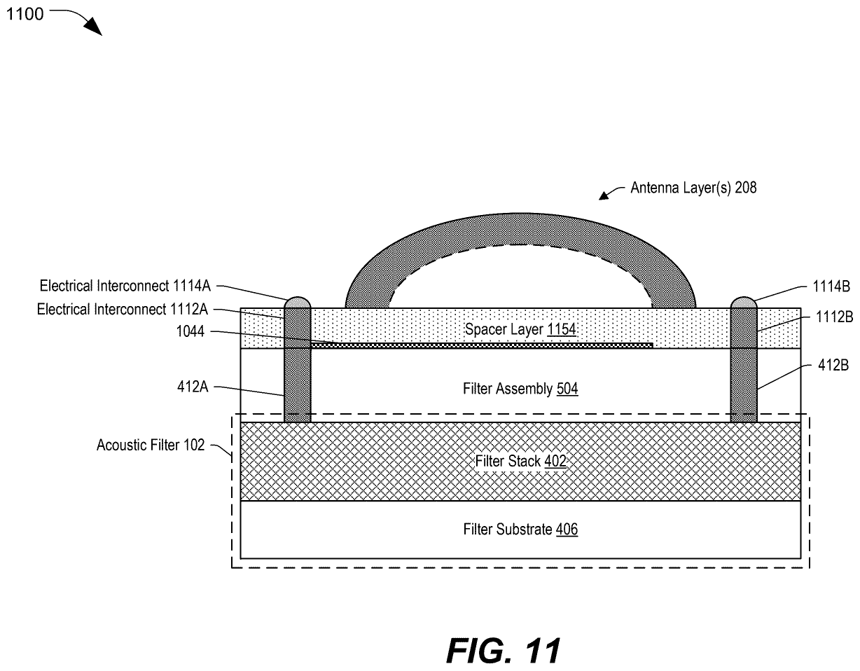

FIG. 11 illustrates a cross-sectional profile view of an exemplary device 1100 (e.g., an acoustic filter device). In the implementation shown in FIG. 11, the device 1100 includes the acoustic filter 102, the filter assembly 504, the metal layer(s) 1044, the antenna layer(s) 208, and a spacer layer 1154 that is between the metal layer(s) 1044 and the antenna layer(s) 208.

The spacer layer 1154 is formed on the metal layer(s) 1044 and at least a portion of the filter assembly 504 (e.g., the IPD layer(s) 120 and the PC 106), and the antenna layer(s) 208 are formed on the spacer layer 1154. In some implementations, the antenna layer(s) 208 are contoured to have a curved shape. In other implementations, the antenna layer(s) 208 are relatively flat. In some implementations, the spacer layer 1154 includes at least one of fused silica, glass, or another dielectric with a relatively low dielectric constant and loss.

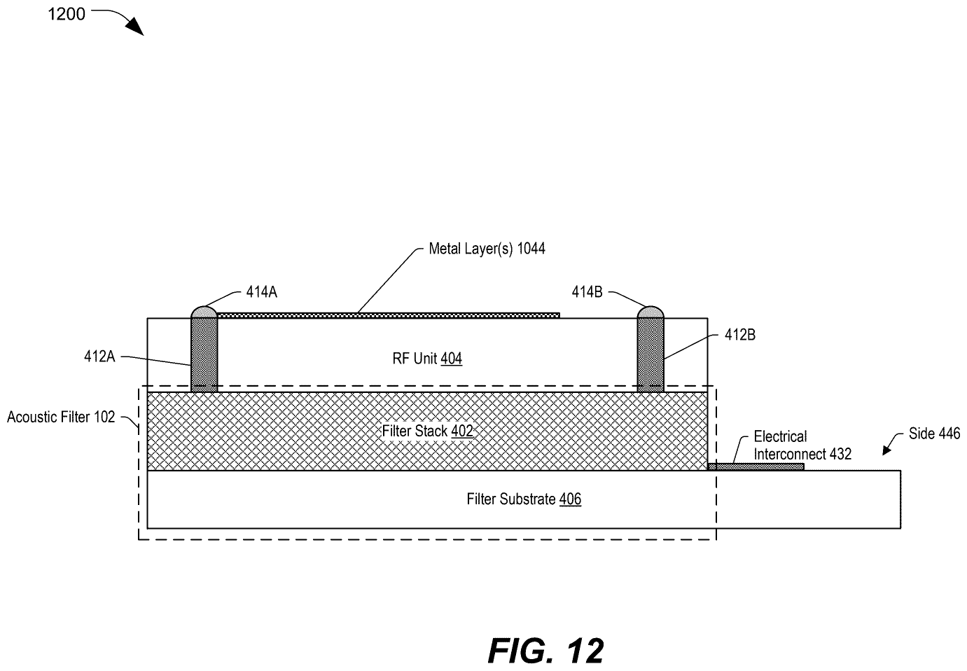

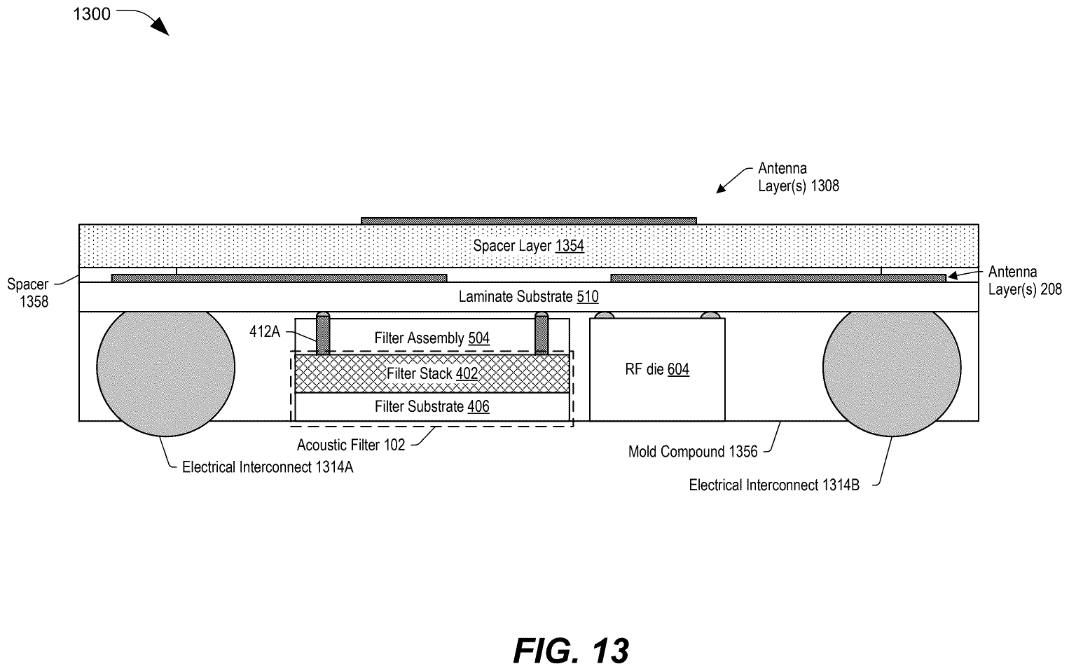

FIG. 12 illustrates a cross-sectional profile view of an exemplary device 1200 (e.g., an acoustic filter device). In the implementation shown in FIG. 12, the device 1200 includes the acoustic filter 102, the RF unit 404, the metal layer(s) 1044, and the electrical interconnect 432 that is formed on the side 446 of the filter substrate 406.

FIG. 13 illustrates a cross-sectional profile view of an exemplary device 1300 (e.g., an acoustic filter device). In the implementation shown in FIG. 13, the device 1300 includes a spacer layer 1354 between one or more antenna layers 1308 and the device 600 of FIG. 6. For example, the device 1300 includes the laminate substrate 510 between the antenna layer(s) 208 and the acoustic filter 102, the filter assembly 504, and the RF die 604, as described with reference to FIG. 6.

Additionally, the device 1300 includes one or more spacers 1358 formed on at least a portion of the laminate substrate 510, at least a portion of the antenna layer(s) 208, or a combination thereof. The device 1300 includes the spacer layer 1354 formed on the spacer(s) 1358, and the antenna layer(s) 1308 formed on the spacer layer 1354. The spacer layer 1354 is thus formed between the antenna layer(s) 208 and the antenna layer(s) 1308. In some implementations, the spacer layer 1354 includes at least one of fused silica, glass, or another dielectric with a relatively low dielectric constant and loss. In some implementations, the spacer(s) 1358 include at least one of fused silica, glass, or another dielectric with a relatively low dielectric constant and loss. In a particular aspect, the spacer 1358 enables formation of an air or vacuum cavity between the spacer layer 1354 and the antenna layer(s) 208.

In some implementations, the filter assembly 504, the acoustic filter 102, and the RF die 604 are least partially encapsulated in a mold compound 1356. In some implementations, one or more electrical interconnects 1314, such as an electrical interconnect 1314A and an electrical interconnect 1314B, are also partially encapsulated in the mold compound 1356. In some aspects, the electrical interconnects 1314 enable the acoustic filter 102, the filter assembly 504, the RF die 604, or a combination thereof, to be electrically connected to one or more other components of the device 1300, one or more off-device components, or a combination thereof.

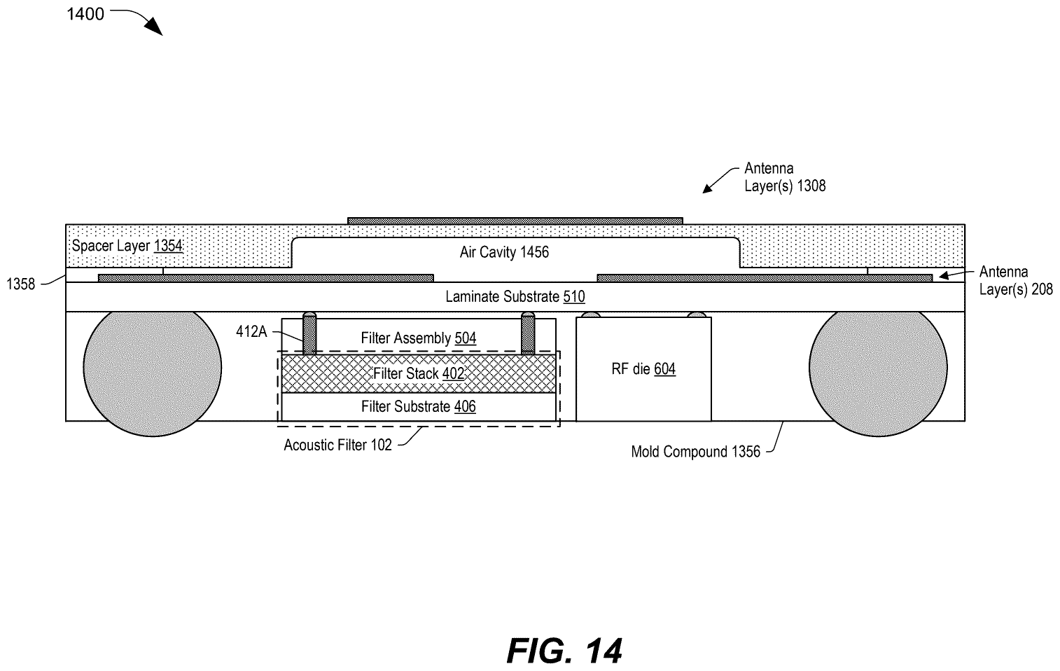

FIG. 14 illustrates a cross-sectional profile view of an exemplary device 1400 (e.g., an acoustic filter device). In the implementation shown in FIG. 14, the device 1400 corresponds to the device 1300 of FIG. 13 with the spacer layer 1354 contoured to have an air cavity 1456. In some implementations, the air cavity 1456 can be a vacuum cavity.

The RF die 604 can include integrated circuitry, such as a plurality of transistors and/or other circuit elements arranged and interconnected to form RF circuits, logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

The dies RF die 604 may include or correspond to particular IC devices that can be arranged and interconnected as a three-dimensional (3D) IC device. In some implementations, the RF die 604 includes one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the RF die 604. Additionally, or alternatively, the RF dies 604 may include or operate as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

In some implementations, the IC dies are electrically connected to, or integrated with, respective substrates. For example, the RF die 604 may be electrically connected (e.g., via one or more contacts or interconnects) to the laminate substrate 510. Any of the conductive interconnects and contacts described herein can include, for example, microbumps, conductive pillars, conductive pads (e.g., for pad to pad bonding), or other similar chiplet-to-chiplet interconnect contacts used for three-dimensional (3D) chiplet stacking.

### Exemplary Sequence for Fabricating a Device/IC Device Including an Acoustic Filter and One or More Integrated Passive Devices

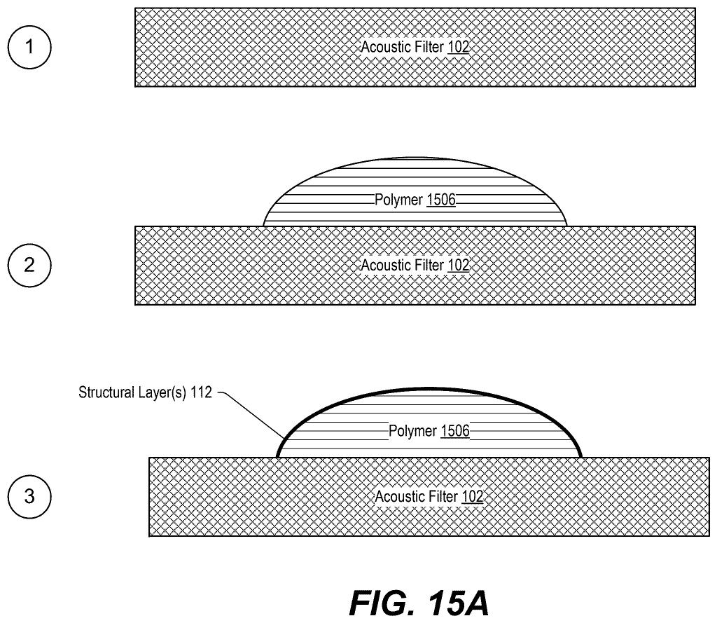

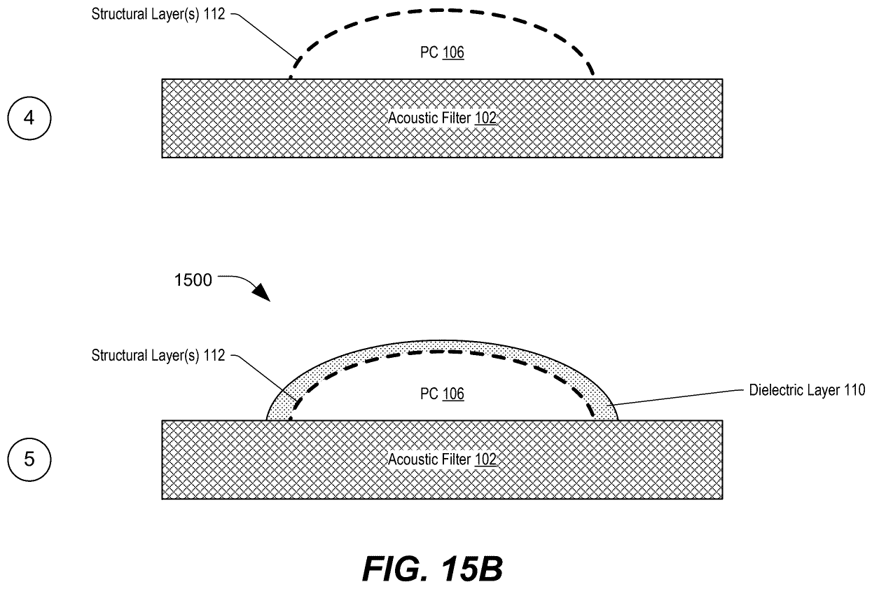

In some implementations, fabricating a device including an acoustic filter and one or more integrated passive devices (e.g., any of the devices 100, 150, 200, 250, 300, 400, 450, 490, 500, 600, 700, 800, 900, 1000, 1100, 1200, 1300, 1400) includes several processes. FIGS. 15A-B and 16 illustrate an exemplary first sequence for fabricating or providing a device that includes an acoustic filter and one or more integrated passive devices, as described with reference to FIG. 1A. FIGS. 15A-B and 17 illustrate an exemplary second sequence for fabricating or providing a device that includes an acoustic filter and one or more integrated passive devices, as described with reference to FIG. 1B.

In some implementations, the first sequence of FIGS. 15A-B and 16 or the second sequence of FIGS. 15A-B and 17 may be used to provide (e.g., during fabrication of) one or more of the device 200, 250, 300, 400, 450, 490, 500, 600, 700, 800, 900, 1000, 1100, 1200, 1300, or 1400. For example, fabricating the device 200, 250, 300, 400, 450, 490, 500, 600, 700, 800, 900, 1000, 1100, 1200, 1300, or 1400 may include one or more additional stages as compared to the first sequence of FIGS. 15A-B and 16 or the second sequence of FIGS. 15A-B and 17.

It should be noted that the first sequence of FIGS. 15A-B and 16, the second sequence of FIGS. 15A-B and 17, or both, may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the first sequence and the second sequence, which are numbered (using circled numbers) in FIGS. 15A-B, 16, and 17. Each of the various stages of the first sequence and the second sequence illustrated in FIGS. 15A-B, 16, and 17 shows a single acoustic filter device being formed. In other implementations, a single acoustic filter device may be formed or a plurality of acoustic filter devices can be formed concurrently.

Stage 1 of FIG. 15A illustrates a state after obtaining an acoustic filter 102. For example, as part of Stage 1, the filter stack 402 may be formed on the filter substrate 406 of FIG. 4B. To illustrate, forming the filter stack 402 can include forming one or more of piezoelectric layers, metal layers, dielectric layers, capping layers, bonding layers, or a combination thereof.

Stage 2 illustrates a state after deposition of a polymer 1506 on the acoustic filter 102. For example, as part of Stage 2, the polymer 1506 includes an organic material that is deposited on the acoustic filter 102 and that forms a curved dome shape (e.g., a bubble).

Stage 3 illustrates a state after formation of the structural layer(s) 112 on the polymer 1506. For example, as part of Stage 3, the structure layer(s) 112 (e.g., including in-organic materials, such as metal, oxide, nitride, or a combination thereof) are formed on the polymer 1506. Forming the structural layer(s) 112 on the polymer 1506 contours the structural layer(s) 112 to have the curved dome shape of the polymer 1506.

Stage 4 of FIG. 5B illustrates a state after formation of the PC 106. For example, as part of Stage 4, at least some of the polymer 1506 is removed through gaps (e.g., etch access holes) in the structural layer(s) 112 to form a curved dome in at least one of the structural layer(s) 112 defining the PC 106 of the acoustic filter 102. In some implementations, the structural layer(s) 112 are formed, in Stage 3 of FIG. 5A, to have the gaps. In other implementations, as part of Stage 4, gaps are formed in the structural layer(s) 112. Removing the polymer 1506 forms an air or vacuum cavity corresponding to the PC 106 and having the curved dome shape of the structural layer(s) 112.

Stage 5 illustrates a state after formation of the dielectric layer 110 on the structural layer(s) 112. For example, as part of Stage 5, dielectric material (e.g., silicon dioxide, silicon nitride, polymer, or a combination thereof) is deposited on the structural layer(s) 112 to form the dielectric layer 110. In some aspects, the dielectric material includes organic dielectric material, such as polymer. Forming the dielectric layer 110 on the structural layer(s) 112 contours the dielectric layer 110 to have the curved dome shape of the structural layer(s) 112.

In some implementations, vapor deposition is used to deposit the dielectric material on the structural layer(s) 112. In some of these implementations, dielectric material may pass through the gaps of the structural layer(s) 112 before the gaps are filled as the dielectric material continues to be deposited on the structural layer(s) 112 to form the dielectric layer 110. In some implementations, a solid organic film or liquid is deposited on the structural layer(s) 112 to form the dielectric layer 110. In some of these implementations, dielectric material does not pass through the gaps of the structural layer(s) 112 due to surface tension. Formation of a single cavity (e.g., the PC 106) of the acoustic filter 102 is provided as an illustrative example, in other examples the polymer 1506 can be deposited in multiple locations on the acoustic filter 102 at Stage 2 to form multiple curved dome shapes that can be used to form multiple cavities (e.g., protective chambers) of the acoustic filter 102.

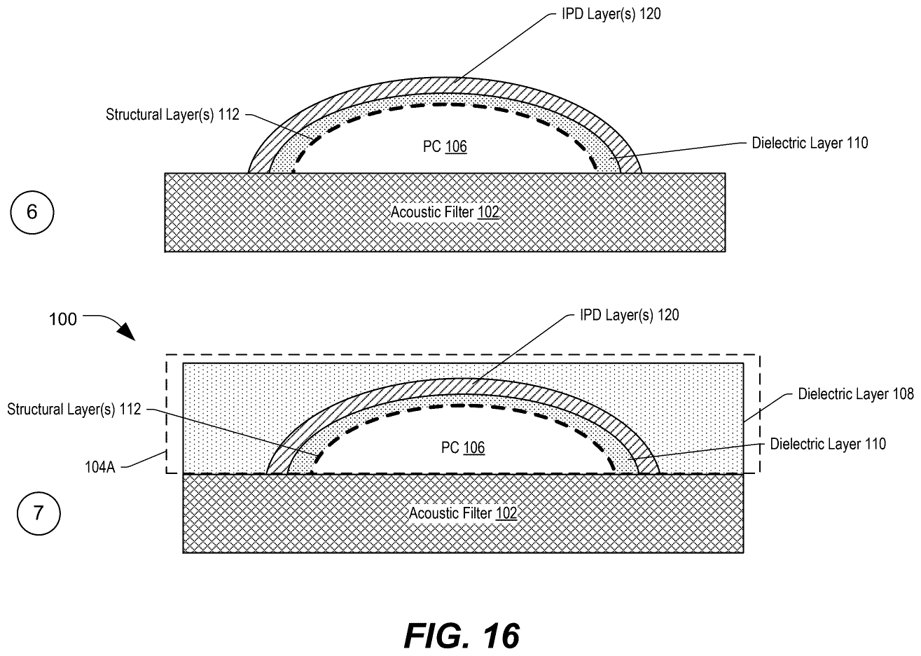

Stage 6 in FIG. 16 illustrates a state, in the first sequence, after formation of the IPD layer(s) 120 on the dielectric layer 110. For example, as part of Stage 6, materials (e.g., metals, dielectrics, resistive materials, or a combination thereof) corresponding to IPDs are deposited on the dielectric layer 110. Patterning and etching may be used to define specific shapes and sizes of passive components, such as resistors, capacitors, or a combination thereof. Forming the IPD layer(s) 120 on the dielectric layer 110 contours the IPD layer(s) 120 to correspond to the dome shape of the dielectric layer 110; the IPD layer(s) 120 are thus contoured to correspond to the dome shape of the PC 106.

Stage 7 of FIG. 16 illustrates a state after formation of the dielectric layer 108. For example, as part of Stage 7, dielectric material (e.g., silicon dioxide, silicon nitride, polymer, or a combination thereof) is deposited on the IPD layer(s) 120 and some exposed portions of the acoustic filter 102 to form the dielectric layer 108.

Formation of the device 100 (e.g., a device including an acoustic filter and one or more IPDs) is complete after Stage 7 of FIG. 16. Although certain Stages are illustrated in FIGS. 15A-B and 16 in forming the device 100, other processes can be included in the fabrication of the device 100 without departing from the scope of the subject disclosure. For example, fabricating the device 100 can include forming the filter stack 402 on the filter substrate 406 to form the acoustic filter 102.

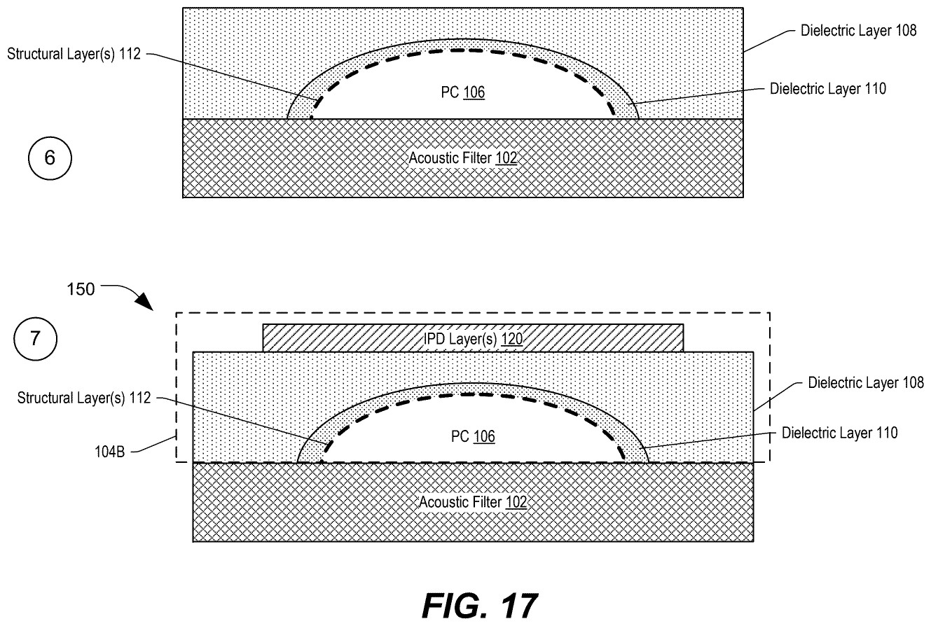

In the second sequence, the dielectric layer 108 is formed prior to formation of the IPD layer(s) 120. Stage 6 in FIG. 17 illustrates a state, in the second sequence, after formation of the dielectric layer 108. For example, as part of Stage 6, dielectric material (e.g., silicon dioxide, silicon nitride, polymer, or a combination thereof) is deposited on the dielectric layer 110 and some exposed portions of the acoustic filter 102 to form the dielectric layer 108. In some implementations, the dielectric layer 108 includes a first dielectric material and the dielectric layer 110 includes a second dielectric material that is distinct from the first dielectric material. In other implementations, the dielectric layer 108 includes the same material as the dielectric layer 110.

Stage 7 of FIG. 16 illustrates a state after formation of the IPD layer(s) 120 on the dielectric layer 108. For example, as part of Stage 7, materials (e.g., metals, dielectrics, resistive materials, or a combination thereof) corresponding to IPDs are deposited on the dielectric layer 108. Patterning and etching may be used to define specific shapes and sizes of passive components, such as resistors, capacitors, or a combination thereof. The IPD layer(s) 120 formed on the dielectric layer 108 can be relatively flat, e.g., not contoured to correspond to the dome shape of the PC 106.

Formation of the device 150 (e.g., a device including an acoustic filter and one or more IPDs) is complete after Stage 7 of FIG. 17. Although certain Stages are illustrated in FIGS. 15A-B and 17 in forming the device 150, other processes can be included in the fabrication of the device 150 without departing from the scope of the subject disclosure. For example, fabricating the device 150 can include forming the filter stack 402 on the filter substrate 406 to form the acoustic filter 102.

In some implementations, the device 100 or the device 150 can be used to form one or more of the device 200, 250, 300, 400, 450, 490, 500, 600, 700, 800, 900, 1000, 1100, 1200, 1300, or 1400. For example, the antenna layer(s) 208 can be formed on the dielectric layer 108 of the device 100 to form the device 200 of FIG. 2A. As another example, the antenna layer(s) 208 can be formed on the IPD layer(s) 120 of the device 150 to form the device 250 of FIG. 2B. In an example, the antenna layer(s) 208 can be formed between Stage 6 and Stage 7 of FIG. 16. To illustrate, the antenna layer(s) 208 can be formed on the IPD layers 120 and the dielectric layer 108 can be formed on the antenna layer(s) 208 and some exposed portions of the acoustic filter 102 to form the device 300 of FIG. 3.

In an example, the electrical interconnect(s) 412 and 414 can be formed in the device 100, 150, 200, or 300 to form the device 400 of FIG. 4A. To illustrate, one or more conductive pillars corresponding to the electrical interconnect(s) 412 can be formed on the acoustic filter 102 prior to formation of the dielectric layer 108 of the device 100 or 150, and the electrical interconnect(s) 414 are formed on the electrical interconnect(s) 412 to form the device 400.

In an example, the electrical interconnect(s) 422 and 424 can be formed in the device 100, 150, 200, or 300 to form the device 450 of FIG. 4B. To illustrate, the filter stack 402 of the acoustic filter 102 is formed on the filter substrate 406 including one or more conductive pillars corresponding to the electrical interconnect(s) 422, and the electrical interconnect(s) 424 are formed on the electrical interconnect(s) 422 prior to or subsequent to formation of the RF unit 404 to form the device 450.

In an example, the electrical interconnect 432 is formed on the device 100, 150, 200, or 300 to form the device 490 of FIG. 4C. To illustrate, the filter stack 402 of the acoustic filter 102 is formed on the filter substrate 406 that extends beyond the filter stack 402. The RF unit 404 is formed as described with respect to formation of the device 100, 150, 200, or 300. The electrical interconnect 432 can be formed on the filter substrate 406 prior to, concurrently with, or subsequent to, formation of the filter stack 402, the RF unit 404, or both, to form the device 490 of FIG. 4C.

In an example, the antenna layer(s) 208 can be formed on the side 542 of the laminate substrate 510 and the device 400 of FIG. 4A, where the RF unit 404 corresponds to the filter assembly 104 or 114, can be electrically connected to the side 544 of the laminate substrate 510 to form the device 500 of FIG. 5. In an example, the RF die 604 can be electrically connected to the side 544 of the laminate substrate 510 of the device 500 to form the device 600 of FIG. 6.

In some examples, the antenna layer(s) 208 are formed on the laminate substrate 510 of the device 600 to correspond to a curved dome shape to form the device 700 of FIG. 7. For example, a polymer (e.g., an organic material) is deposited on the laminate substrate 510, and the polymer has a curved dome shape (e.g., a bubble). The structural layer(s) 712 are formed on the polymer. Forming the structural layer(s) 712 on the polymer contours the structural layer(s) 712 to have the curved dome shape of the polymer. The polymer is removed through gaps in the structural layer(s) 712 to form an air or vacuum cavity between the structural layer(s) 712 and the laminate substrate 510. The antenna layer(s) 208 are formed on the structural layer(s) 712. Forming the antenna layer(s) 208 on the structural layer(s) 712 contours the antenna layer(s) 208 to have the curved dome shape of the structural layer(s) 712.

In an example, the electrical interconnect(s) 412, 422, and 822, the electrical interconnect(s) 832, and the antenna layer(s) 208 are formed in the device 100 or 150 to form the device 800 of FIG. 8. For example, the filter stack 402 is formed on the filter substrate 406 having the electrical interconnect(s) 422. The electrical interconnect(s) 822 are formed in the filter stack 402. The electrical interconnect(s) 412 are formed on the filter stack 402 prior to formation of the dielectric layer 108 of the filter assembly 504. The electrical interconnect(s) 414 are formed on the electrical interconnect(s) 412. The antenna layer(s) 208 are formed on the filter substrate 406. The electrical interconnect(s) 832 are formed on the filter substrate 406.

In an example, the RF die 604, the filter assembly 504, and the acoustic filter 102 are electrically connected to the laminate substrate 510 as described with reference to FIG. 6. The electrical interconnect 922 is also formed on the laminate substrate 510, the mold compound 956 is deposited to at least partially encapsulate the acoustic filter 102, the filter assembly 504, the RF die 604, and the electrical interconnect 922, and the antenna layer(s) 208 are formed on the mold compound 956 to form the device 900 of FIG. 9.

The metal layer(s) 1044 can be added at various Stages of forming the device 100, 150, 200, 250, 300, 400, 450, 490, 500, 600, 700, 800, 900, 1000, 1100, 1200, 1300, or 1400. For example, the metal layer(s) 1044 can be added to form the device 1000, 1100, or 1200. In an example, the RF die 604, the filter assembly 504, and the acoustic filter 102 are electrically connected to the laminate substrate 510 as described with reference to FIG. 6. The mold compound 1356 is deposited on the side 544 of the laminate substrate 510 and the antenna layers 208 are formed on the side 542 of the laminate substrate 510. The spacer 1358 is formed on at least a portion of the laminate substrate 510, at least a portion of the antenna layer(s) 208, or both. The spacer layer 1354 is formed on the spacer 1358 and the antenna layer(s) 1308 are formed on the spacer layer 1354 to form the device 1300 or 1400.

### Exemplary Flow Diagram of a Method for Fabricating a Device/Integrated Device Including an Acoustic Filter and One or More Integrated Passive Devices

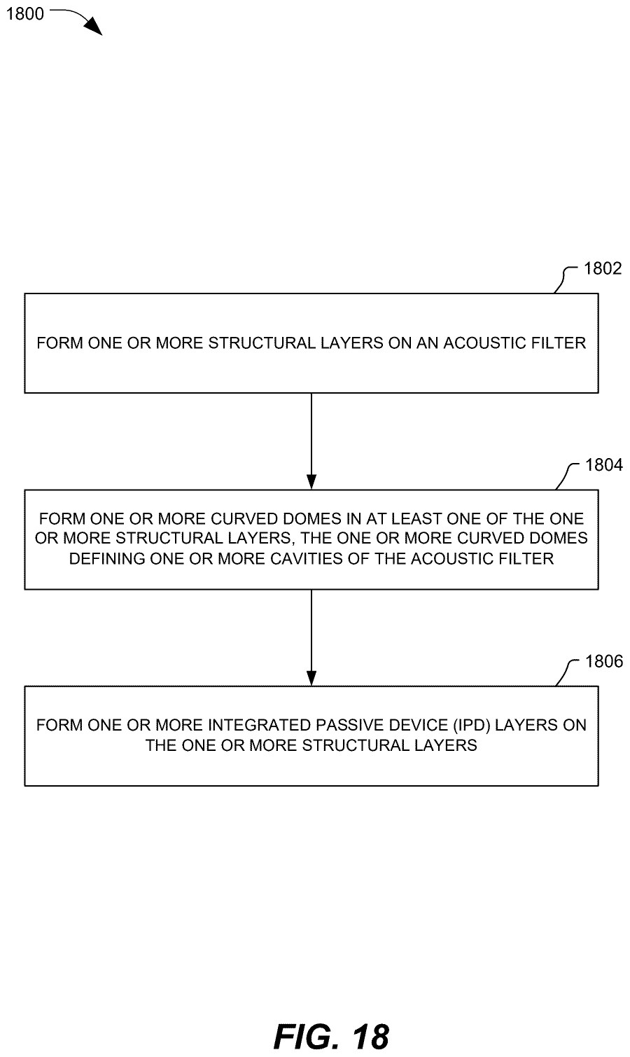

In some implementations, fabricating a device including an acoustic filter and one or more passive devices includes several processes. FIG. 18 illustrates an exemplary flow diagram of a method 1800 of fabricating an illustrative device that includes an acoustic filter and one or more passive devices. In a particular aspect, one or more operations of the method 1800 are performed by one or more processors of a fabrication system. In some implementations, operations of the method 1800 may be stored as instructions by a non-transitory computer-readable storage medium, and the instructions may be executable by at least one processor to cause the at least one processor to perform operations of the method 1800. In some implementations, the method 1800 of FIG. 18 may be used to provide or fabricate any of the device 100, 150, 200, 250, 300, 400, 450, 490, 500, 600, 700, 800, 900, 1000, 1100, 1200, 1300, or 1400.

It should be noted that the method 1800 of FIG. 18 may combine one or more processes in order to simplify and/or clarify the method for providing or fabricating an integrated circuit device. In some implementations, the order of the processes may be changed or modified.

The method 1800 includes forming one or more structural layers on an acoustic filter, at block 1802. For example, Stage 3 of FIG. 15A illustrates and describes examples of forming the structural layer(s) 112 on the polymer 1506. The structural layer(s) of the method 1800 can include the structural layer(s) 112 of the device 100 of FIG. 1A or the device 150 of FIG. 1B.

The method 1800 includes forming one or more curved domes in at least one of the one or more structural layers, the one or more curved domes defining one or more cavities of the acoustic filter, at block 1804. For example, Stage 3 of FIG. 15A and Stage 4 of FIG. 15B illustrate and describe examples of forming the structural layer(s) 112 contoured to have one or more curved domes that define one or more cavities (e.g., the PC 106). The one or more cavities of the method 1800 can include the PC 106 of the device 100 of FIG. 1A or the device 150 of FIG. 1B.

The method 1800 includes forming one or more integrated passive device (IPD) layers on the one or more structural layers, at block 1806. For example, Stage 6 of FIG. 16 illustrates and describes examples of forming the IPD layer(s) 120 on the dielectric layer 110 that is on the structural layer(s) 112. In this example, the IPD layers of the method 1800 can include the IPD layer(s) 120 of the device 100 of FIG. 1A. As another example, Stage 7 of FIG. 17 illustrates and describes examples of forming the IPD layer(s) 120 on the dielectric layer 108, that is on the dielectric layer 110, that is on the structural layer(s) 112. In this example, the IPD layers of the method 1800 can include the IPD layer(s) 120 of the device 150 of FIG. 1B.

In some implementations, the method 1800 also includes forming the antenna layer(s) 208, as described with reference to FIGS. 2A, 2B, and 3. In some implementations, the method 1800 also includes forming the electrical interconnects 412, 414, as described with reference to FIG. 4A. In some implementations, the method 1800 also includes forming the electrical interconnects 422, 424, as described with reference to FIG. 4B. In some implementations, the method 1800 also includes forming the electrical interconnect 432, as described with reference to FIG. 4C.

In some implementations, the method 1800 also includes forming the antenna layer(s) 208 on the side 542 of the laminate substrate 510 and electrically connecting the acoustic filter 102 and the filter assembly 504 to the side 544 of the laminate substrate 510, as described with reference to FIG. 5. In some implementations, the method 1800 also includes electrically connecting the RF die 604 to the side 544 of the laminate substrate 510, as described with reference to FIG. 6. In some implementations, the method 1800 also includes forming the antenna layer(s) 208 contoured to correspond to a curved dome shape on the side 542 of the laminate substrate 510, as described with reference to FIG. 7.

In some implementations, the method 1800 also includes forming the filter assembly 504 on the filter stack 402 that is on the side 446 of the filter substrate 406 and forming the antenna layer(s) 208 on the side 448 of the filter substrate 406, as described with reference to FIG. 8. In some implementations, the method 1800 also includes at least partially encapsulating the filter assembly 504, the acoustic filter 102, and the RF die 604 in the mold compound 956, and forming the antenna layer(s) 208 on the mold compound 956, as described with reference to FIG. 9.

In some implementations, the method 1800 also includes forming the metal layer(s) 1044 on the RF unit 404 that is on the acoustic filter 102, as described with reference to FIG. 10. In some implementations, the method 1800 also includes forming the metal layer(s) 1044 on the filter assembly 504 that is on the acoustic filter 102 and forming the antenna layer(s) 208 on the spacer layer 1154 that is on the metal layer(s) 1044, as described with reference to FIG. 11. In some implementations, the method 1800 also includes forming the metal layer(s) 1044 on the RF unit 404 that is on the acoustic filter 102 and forming the electrical interconnect 432 on the filter substrate 406, as described with reference to FIG. 12.

In some implementations, the method 1800 also includes at least partially encapsulating the filter assembly 504, the acoustic filter 102, and the RF die 604 that are in the mold compound 1356 on the side 544 of the laminate substrate 510, forming the antenna layer(s) 208 on the side 542 of the laminate substrate 510, forming the spacer layer 1354 on the spacer(s) 1358, and forming the antenna layer(s) 1308 on the spacer layer 1354, as described with reference to FIG. 13. Forming the spacer layer 1354 can include forming the spacer layer 1354 having the air cavity 1456 (or a vacuum cavity), as described with reference to FIG. 14.

### Exemplary Electronic Devices

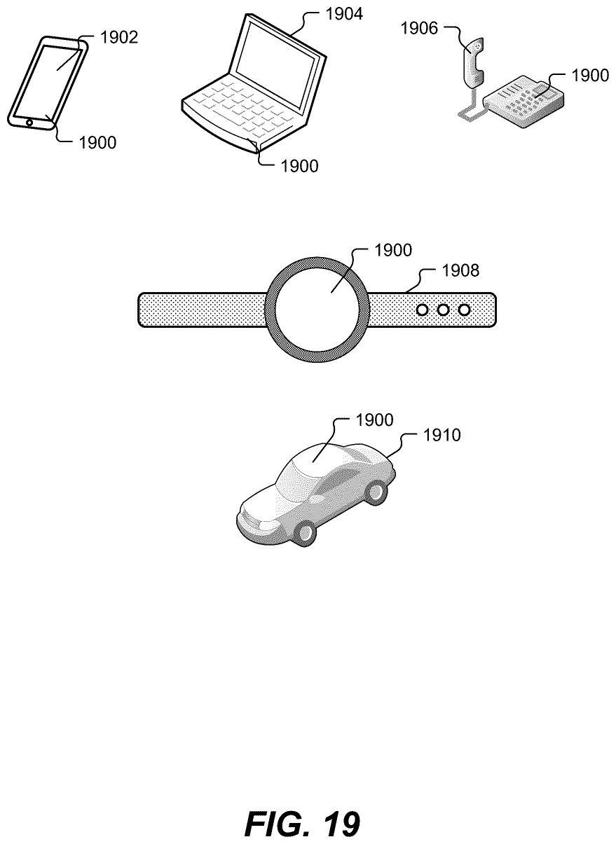

FIG. 19 illustrates various electronic devices that may include or be integrated with any of the device 100, 150, 200, 250, 300, 400, 450, 490, 500, 600, 700, 800, 900, 1000, 1100, 1200, 1300, 1400, or any device that includes an acoustic filter and one or more integrated passive devices. For example, a mobile phone device 1902, a laptop computer device 1904, a fixed location terminal device 1906, a wearable device 1908, or a vehicle 1910 (e.g., an automobile or an aerial device) may include a device 1900. The device 1900 can include, for example, any of device 100, 150, 200, 250, 300, 400, 450, 490, 500, 600, 700, 800, 900, 1000, 1100, 1200, 1300, or 1400, and/or any other integrated device that includes an acoustic filter and one or more integrated passive devices described herein. The devices 1902, 1904, 1906 and 1908 and the vehicle 1910 illustrated in FIG. 19 are merely exemplary. Other electronic devices may also feature the device 1900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-19 may be rearranged and/or combined into a single component, process, feature or function or embodied in several components, processes, or functions. Additional elements, components, processes, and/or functions may also be added without departing from the disclosure. It should also be noted FIGS. 1A-19 and its corresponding description in the present disclosure is not limited to dies and/or ICs. In some implementations, FIGS. 1A-19 and its corresponding description may be used to manufacture, create, provide, and/or produce devices and/or integrated devices. In some implementations, a device may include a die, an integrated device, an embedded multi-chip package, an IPD, a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, an acoustic filter device includes an acoustic filter; one or more structural layers forming one or more curved domes that define one or more cavities of the acoustic filter; and one or more integrated passive device (IPD) layers on the one or more structural layers.

Example 2 includes the acoustic filter device of Example 1, wherein the one or more IPD layers are contoured to correspond to a shape of the one or more curved domes.

Example 3 includes the acoustic filter device of Example 1 or Example 2, further comprising one or more antenna layers.

Example 4 includes the acoustic filter device of Example 3, wherein the one or more antenna layers are on the same side of a filter substrate of the acoustic filter as the one or more IPD layers.

Example 5 includes the acoustic filter device of Example 3 or Example 4, and further includes a laminate substrate between the one or more IPD layers and the one or more antenna layers.

Example 6 includes the acoustic filter device of Example 5, and further includes a radio frequency (RF) die, wherein the RF die and the one or more IPD layers are on a first side of the laminate substrate.

Example 7 includes the acoustic filter device of any of Examples 3 to 6, wherein the one or more antenna layers are contoured to correspond to a shape of the one or more curved domes.

Example 8 includes the acoustic filter device of Example 3 or Example 7, and further includes a filter substrate between a filter stack of the acoustic filter and the one or more antenna layers.

Example 9 includes the acoustic filter device of any of Examples 3 to 8, and further includes a radio frequency (RF) die, wherein the RF die and the one or more IPD layers are on a first side of a laminate substrate.

Example 10 includes the acoustic filter device of Example 9, and further includes mold compound at least partially encapsulating the acoustic filter, the one or more IPD layers, and the RF die, wherein the one or more antenna layers are on the mold compound.

Example 11 includes the acoustic filter device of Example 9 or Example 10, and further includes a spacer layer between a first antenna layer and a second antenna layer of the one or more antenna layers.

Example 12 includes the acoustic filter device of Example 11, wherein the spacer layer includes at least one of fused silica, glass, or another dielectric with a relatively low dielectric constant.

Example 13 includes the acoustic filter device of Example 11 or Example 12, wherein the spacer layer includes an air cavity.

Example 14 includes the acoustic filter device of any of Examples 1 to 13, and further includes a filter substrate, wherein a filter stack of the acoustic filter is on a first side of the filter substrate.

Example 15 includes the acoustic filter device of Example 14, and further includes an electrical interconnect that extends from the first side to a second side of the filter substrate.

Example 16 includes the acoustic filter device of Example 14 or Example 15, and further includes an electrical interconnect on the first side of the filter substrate.

Example 17 includes the acoustic filter device of any of Examples 1 to 16, and further includes one or more metal layers on the one or more structural layers and connected to at least one electrical interconnect.

Example 18 includes the acoustic filter device of Example 17, wherein the one or more metal layers include at least one of a reinforcement layer, an electromagnetic interference (EMI) shielding layer, a heat spreader, an inductor-resistor-capacitor (LRC) layer, a functional layer, an antenna feed, a matching network, a micro strip line, a transmission line, an antenna, or a routing layer.

Example 19 includes the acoustic filter device of Example 17 or Example 18, and further includes one or more antenna layers; and a spacer layer between the one or more metal layers and the one or more antenna layers.

According to Example 20, a method of fabricating an acoustic filter device includes forming one or more structural layers on an acoustic filter; forming one or more curved domes in at least one of the one or more structural layers, the one or more curved domes defining one or more cavities of the acoustic filter; and forming one or more integrated passive device (IPD) layers on the one or more structural layers.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An acoustic filter device comprising:
an acoustic filter;
one or more structural layers forming one or more curved domes that define a one or more cavities of the acoustic filter; and
one or more integrated passive device (IPD) layers on the one or more structural layers.

2. The acoustic filter device of claim 1, wherein the one or more IPD layers are contoured to correspond to a shape of the one or more curved domes.

3. The acoustic filter device of claim 1, further comprising one or more antenna layers.

4. The acoustic filter device of claim 3, wherein the one or more antenna layers are on the same side of a filter substrate of the acoustic filter as the one or more IPD layers.

5. The acoustic filter device of claim 3, further comprising a laminate substrate between the one or more IPD layers and the one or more antenna layers.

6. The acoustic filter device of claim 5, further comprising a radio frequency (RF) die, wherein the RF die and the one or more IPD layers are on a first side of the laminate substrate.

7. The acoustic filter device of claim 3, wherein the one or more antenna layers are contoured to correspond to a shape of the one or more curved domes.

8. The acoustic filter device of claim 3, further comprising a filter substrate between a filter stack of the acoustic filter and the one or more antenna layers.

9. The acoustic filter device of claim 3, further comprising a radio frequency (RF) die, wherein the RF die and the one or more IPD layers are on a first side of a laminate substrate.

10. The acoustic filter device of claim 9, further comprising mold compound at least partially encapsulating the acoustic filter, the one or more IPD layers, and the RF die, wherein the one or more antenna layers are on the mold compound.

11. The acoustic filter device of claim 9, further comprising a spacer layer between a first antenna layer and a second antenna layer of the one or more antenna layers.

12. The acoustic filter device of claim 11, wherein the spacer layer includes at least one of fused silica, glass, or another dielectric with a relatively low dielectric constant.

13. The acoustic filter device of claim 11, wherein the spacer layer includes an air cavity.

14. The acoustic filter device of claim 1, further comprising a filter substrate, wherein a filter stack of the acoustic filter is on a first side of the filter substrate.

15. The acoustic filter device of claim 14, further comprising an electrical interconnect that extends from the first side to a second side of the filter substrate.

16. The acoustic filter device of claim 14, further comprising an electrical interconnect on the first side of the filter substrate.

17. The acoustic filter device of claim 1, further comprising one or more metal layers on the one or more structural layers and connected to at least one electrical interconnect.

18. The acoustic filter device of claim 17, wherein the one or more metal layers include at least one of a reinforcement layer, an electromagnetic interference (EMI) shielding layer, a heat spreader, an inductor-resistor-capacitor (LRC) layer, a functional layer, an antenna feed, a matching network, a micro strip line, a transmission line, an antenna, or a routing layer.

19. The acoustic filter device of claim 17, further comprising:
one or more antenna layers; and
a spacer layer between the one or more metal layers and the one or more antenna layers.

20. A method of fabricating an acoustic filter device, the method comprising:
forming one or more structural layers on an acoustic filter;
forming one or more curved domes in at least one of the one or more structural layers, the one or more curved domes defining one or more cavities of the acoustic filter; and
forming one or more integrated passive device (IPD) layers on the one or more structural layers.
